(19) United States
(12) Patent Application Publication
(10) Pub. No.: US 2010/0183984 A1
(43) Pub. Date: Jul. 22, 2010

(54) MULTIPLEXING OF PULSED SOURCES

(75) Inventor: Peter Choi, Orsay (FR)

Correspondence Address: GREER, BURNS & CRAIN, 300 S WACKER DR, 25TH FLOOR, CHICAGO, IL, 60606, US

(73) Assignee: NANO UV, Villebon Sur Yvette (FR)

(21) Appl. No.: 12/600,193

(22) PCT Filed: Feb. 19, 2008
(86) PCT No.: PCT/IB08/51798

§ 371 Date: Nov. 13, 2009

(51) Int. Cl. G03F 7/20; G03B 27/52; G21G 4/00

(52) U.S. Cl. 430/319; 355/70; 250/494.1

(57) ABSTRACT

A process and related apparatus for generating an output radiation through an output aperture, including generating pulsed radiations by a plurality of radiation sources, each source being arranged for respectively (i) generating within a respective plasma a respective pulsed elementary radiation whose wavelengths include a respective desired range, and (ii) directing rays of its respective elementary radiation on the output aperture. For each source, refractive indices of rays are distributed in a respective control region through which its respective elementary radiation passes and located in its respective plasma, to selectively deviate rays of its respective elementary radiation as a function of their wavelength, and temporally multiplexing the radiation sources to obtain at the output aperture the output radiation.

### TECHNICAL FIELD

The present invention relates to a method for generating an output radiation through an output aperture.

The invention also relates to a device implementing this method and to a photolithography apparatus comprising said device.

### STATE OF THE ART

Methods and devices for generating a pulsed radiation are already known. These methods and devices are for example used for the generation of a radiation for an optical chain in the domain of photolithography of a photosensitive wafer. Such an optical chain comprises:

a pulsed source generating a radiation in a range of desired wavelengths;

an optical system that receives the radiation from the pulsed source and processes it (for example by collimating it and/or making it converge);

a mask that receives the radiation from the optical system and that only lets pass the radiation rays that are in front of a transmission pattern, the rest of the radiation being stopped by the mask; and

a wafer that receives the rays that have been not stopped by the mask.

The surface of the wafer being exposed to the radiation is covered by a photoresist or a photosensitive product. The rays hitting the wafer react with the product, and form on the surface of the wafer a pattern corresponding to the transmission pattern of the mask.

The desired average power of a pulsed source for EUV photolithography would be of the order of 100 W, for instance 150 W, but would be to advantage as high as possible. The higher the power, the better it is. A high power allows a higher throughput of the process.

The desired frequency of the pulsed radiation of a source for EUV photolithography would be of the order of 10 kHz, for example 7 kHz, but would be to advantage as high as possible. The higher the frequency, the better it is. A high frequency allows a statistical homogeneity of the granularity of the rays arriving on the wafer while scanning the wafer.

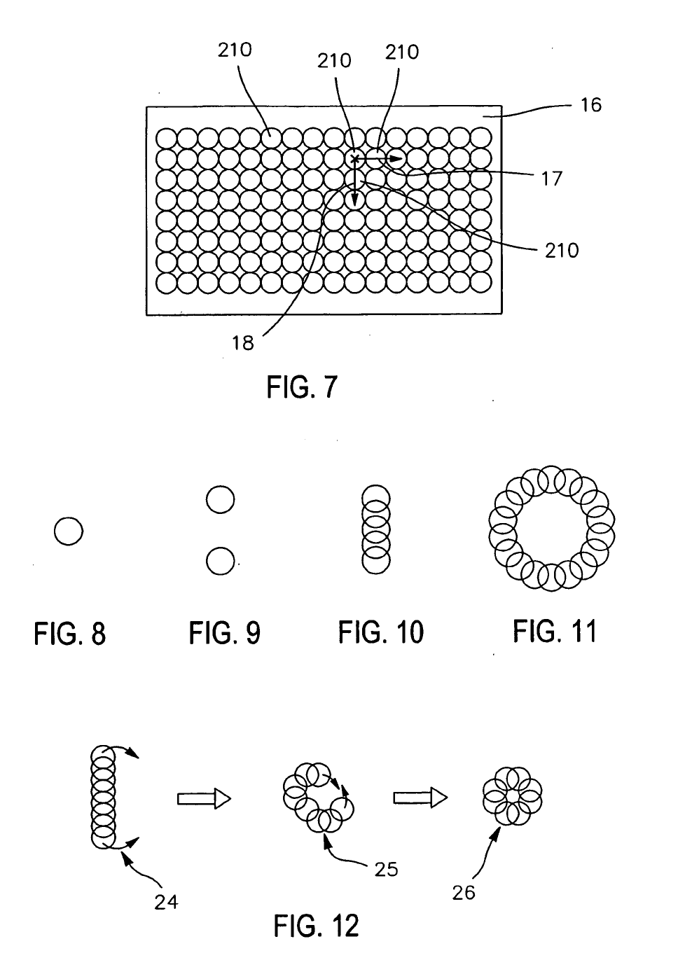

Document U.S. Pat. No. 6,861,656 discloses a high-luminosity EUV-source device for use in extreme ultraviolet and soft x-ray lithography systems, this device being able to generate an output radiation having a high power and a high frequency. This device comprises a plurality of pulsed EUV-light sources. Each pulsed source emits light pulses, each light pulse being reflected by an associated planar mirror. As shown in FIGS. 7a and 7b of U.S. Pat. No. 6,861,656, these pulsed sources can be time multiplexed, in order to obtain a composite light emission that is substantially continuous. Nevertheless, the time multiplexing according to U.S. Pat. No. 6,861,656 is difficult to implement, as it requires changing simultaneously the angular positions of the planar mirrors.

The goal of the invention is to present a method for generating a output radiation having a high power and/or a high frequency, easier to implement than those of the prior art, and a device implementing this method.

### SUMMARY OF THE INVENTION

An aspect of the invention concerns a process for generating an output radiation through an output aperture, said process comprising:

generating pulsed radiations by a plurality of radiation sources, each source being arranged for respectively
(i) generating within a respective plasma a respective pulsed elementary radiation whose wavelengths include a respective desired range,
(ii) directing rays of its respective elementary radiation on said output aperture,

for each source, distributing refractive indices of rays in a respective control region through which its respective elementary radiation passes and located in its respective plasma, so as to selectively deviate rays of its respective elementary radiation as a function of their wavelength,
and

temporally multiplexing said radiation sources so as to obtain at the output aperture said output radiation.

Temporal multiplexing typically means coordinating in time, by a temporal multiplexer, of the generation of radiations one relative to the others.

The process according to the invention can further comprise detecting a breakdown of one of the radiation sources, and generating an elementary radiation by a reserve source that replaces said broken down source.

The process according to the invention can further comprise a measurement of a power of the output radiation, and a control of the temporal multiplexing according to the measurement of the power of the output radiation. The pulsed radiations generation can comprise generating elementary radiations one after the other by operating sources, and generating at least one elementary radiation by at least one supportive source if the power of the output radiation generated by the operating sources is lower than a minimum threshold value.

A plurality of elementary radiations can be simultaneously generated in order to create a desired radiation pattern. The process according to the invention can further comprise a dynamical modification of the desired pattern over the time. That the dynamical modification of the radiation pattern can comprise, for at least one of the radiation sources, a modification of an angular position of at least one mirror reflecting to the output aperture rays generated by said radiation source.

An average frequency of the output radiation can be higher than a maximum frequency of each radiation source. Each source can have a different maximum frequency.

An other aspect of the invention concerns a device for generating an output radiation through an output aperture, said device comprising:

a plurality of radiation sources, each source comprising means for generating a respective pulsed elementary radiation whose wavelengths include a respective desired range, each source being arranged for directing rays of its respective elementary radiation on said output aperture, each source comprising a respective plasma in which its respective elementary radiation is generated and deviation means comprising means for setting up a controlled distribution of refractive indices of rays in a respective control region through which its respective elementary radiation passes and located in its respective plasma, so as to selectively deviate rays of its respective elementary radiation as a function of their wavelength, and

a temporal multiplexer for temporally multiplexing the radiation sources in order to obtain at the output aperture said output radiation.

The device according to the invention can further comprise means for detecting a breakdown of at least one of the pulsed sources, the plurality of radiation sources comprising a reserve group comprising at least one reserve source arranged to generate radiations in place of at least one broken down source. The reserve group preferably comprises a plurality of reserve sources, each reserve source being arranged to generate radiations in place of one of the broken down sources.

The device according to the invention can further comprise means to measure a power of the output radiation, and means to control the temporal multiplexer according to a measurement of the power of the output radiation. The measured power of the output radiation can be a time averaged power. The means to measure the power of the output radiation can comprise, for each radiation source, means to measure a power of the pulsed radiation generated by said source. The plurality of radiation sources can comprise:

an operation group comprising sources arranged to generate radiations one after the other, and

a supportive group comprising at least one supportive source arranged to generate radiations if the power of the output radiation generated by the operation group is lower than a minimum threshold value (the supportive group preferably comprising a plurality of supportive sources).

The temporal multiplexer can be arranged to command simultaneous generations of radiations by more than one source in order to create a desired radiation pattern. The device according to the invention can further comprise means for dynamically modifying the radiation pattern. The modification means can comprise, for at least one of the radiation sources (preferably for a plurality of radiation sources or for each radiation source), at least one respective mirror reflecting to the output aperture rays generated by said source.

Nevertheless, at least one of the radiation sources (preferably a plurality of radiation sources or each radiation source) can be arranged to generate an elementary radiation, rays of which reach the output aperture and are not reflected from said radiation source to the output aperture.

Each source can generate its respective pulsed elementary radiation through a respective source aperture, a plurality of source apertures being grouped on a surface, the surface being preferably a plane or a sphere portion, each aperture grouped on the surface being adjacent to at least one other aperture grouped on the surface along a first direction and adjacent to at least one other aperture grouped on the surface along a second direction different from the first direction.

Each radiation source can have a respective maximum generation frequency of elementary radiations, the temporal multiplexer being arranged to give to the output radiation an average frequency that is higher than all the maximum frequencies of the sources.

The device according to the invention can comprise for at least one radiation source (preferably for a plurality of radiation sources or for each radiation source) a respective filtering window on the downstream side of the control region of said source, said filtering window:

letting pass the rays generated by said source and inside of the desired wavelength range of said source, and

preventing the rays generated by said source and outside of the desired range of said source from reaching the output aperture.

The filtering window can be substantially the same one for several of the sources (preferably for all the radiation sources), and is preferably the output aperture.

The means for setting up a controlled distribution of refractive indices can comprise, for one, some or all the sources, means for controlling the electron density distribution in said control region.

At least one (preferably each) desired range can be located in the wavelength interval from 0 nanometre to 100 nanometres, preferably in the extreme UV spectrum or soft X-rays spectrum.

An other aspect of the invention concerns a lithography apparatus comprising a generating device according to the invention.

An other aspect of the invention concerns a method of producing microelectronic components, particularly semiconductor components, using a lithography apparatus according to the invention.

### DETAILED DESCRIPTION OF THE FIGURES AND OF REALIZATION MODES OF THE INVENTION

Other advantages and characteristics of the invention will appear upon examination of the detailed description of embodiments which are no way limitative, and of the appended drawings in which:

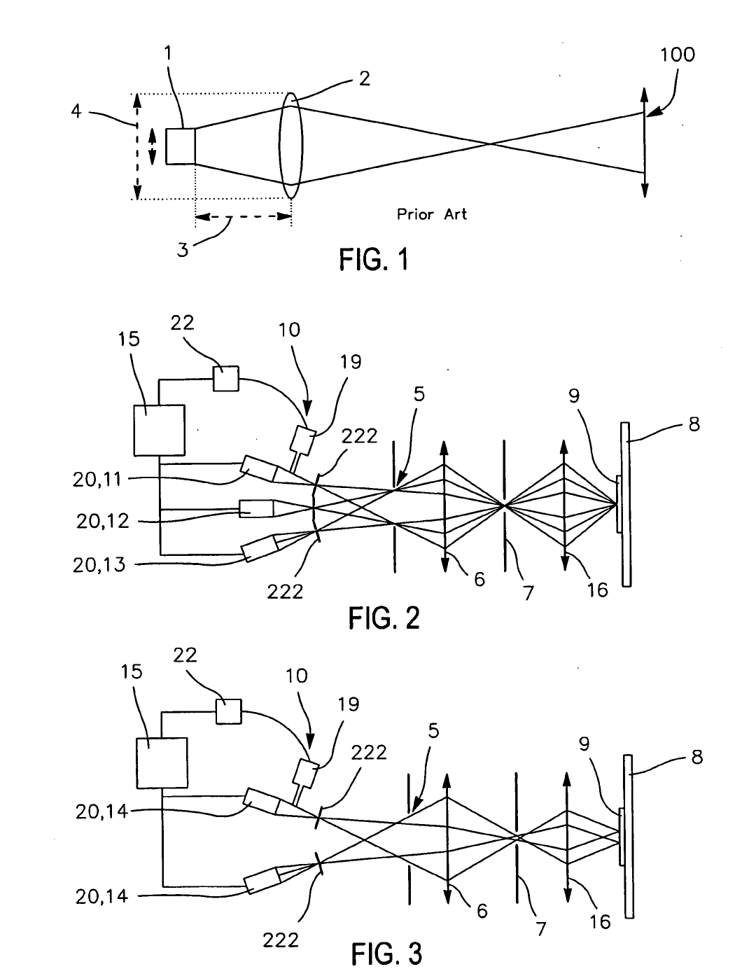

FIG. 1 illustrates a radiation source according to prior art,

FIGS. 2 and 3 are respectively a first and second schematic view of a first realisation mode of a lithography apparatus according to the invention,

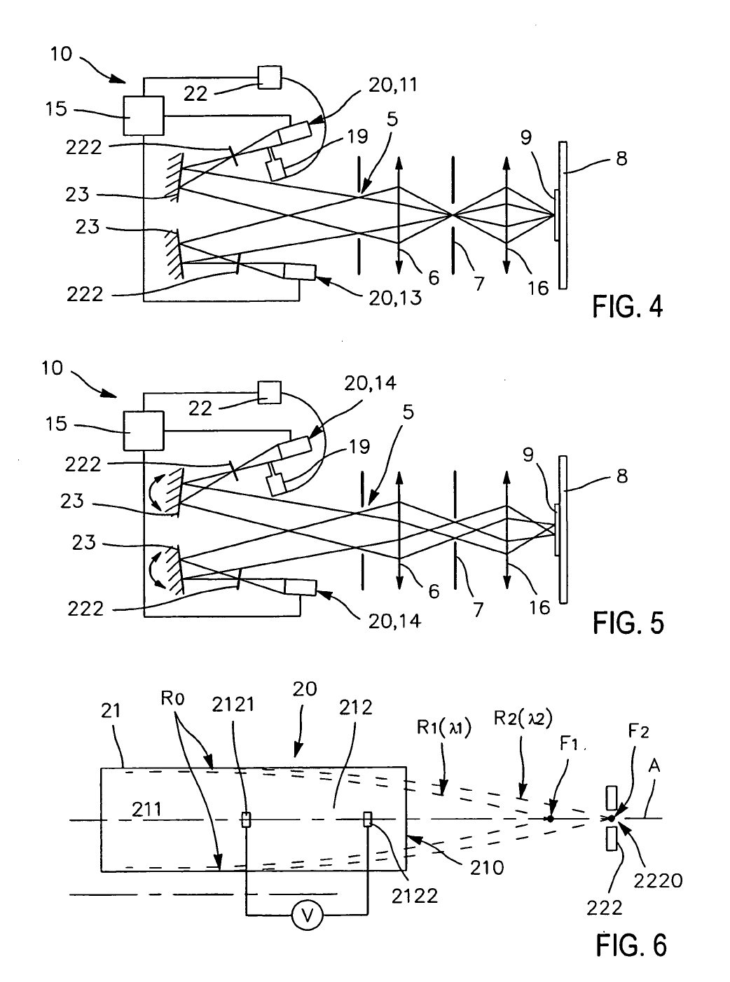

FIGS. 4 and 5 are respectively a first and second schematic view of a second realisation mode of a lithography apparatus according to the invention,

FIG. 6 is a schematic view of one of the pulsed sources comprised in the lithography apparatuses of FIGS. 2 to 5,

FIG. 7 illustrates an arrangement of the apertures of the pulsed sources of the lithography apparatus of FIGS. 2 and 3,

FIGS. 8 to 11 illustrate different types of radiation patterns obtained by simultaneous generations of radiations by a plurality of the pulsed sources of the lithography apparatuses of FIGS. 2 to 5, and

FIG. 12 illustrates a dynamical modification of a radiation pattern.

A typical radiation source according to prior art is illustrated in FIG. 1. This radiation source comprises a light emission portion 1 and a lens 2.

The light emitted by the emission portion 1 is divergent. The lens 2 is placed in front of the portion 1 to focalize the rays emitted by the portion 1. In a lithography apparatus, as disclosed before, the power emitted by the portion 1 has a high value: the lens 2 is not placed close to the portion 1, in order to be not damaged. The bigger the distance 3 between the lens 2 and the portion 1, the bigger is the diameter 4 of the lens 2, because the lens 2 must receive all the rays emitted by the portion 1.

It is reminded here that the etendue is a parameter to assess the quantity of electromagnetic beams generated by an optical source, and how these beams are emitted. The etendue is an invariant of a source and proportional to the surface of the source multiplied by the solid angle in which the source surface emits the beams. The unit of the etendue is therefore mm².sr (millimeter².steradian). As a simple example, a perfect laser, no matter how big the surface from which it emits is, has a theoretical etendue that equals zero, as the solid angle in which a laser theoretically emits is null.

A lens assembly 100 processes the rays from the lens 2 and directs these rays to a mask and a wafer. The lens assembly 100 of a current apparatus for EUV photolithography can only support a maximum etendue of 1-3 mm²/sr. If the etendue of the source 1 is bigger, the efficiency of the photolithography apparatus would decreased, as a portion of the radiation would not be collected by the lens assembly 100.

The lens 2 has a big diameter 4. Thus, the combination of the source 1 and the lens 2 has a big volume, and only a small number of sources 1 (typically two sources) can be combined. That means that each source 1 must have a high power, and thus a big diameter and a big etendue, and can hardly be multiplexed. To solve this problem, the device according to U.S. Pat. No. 6,861,656 comprises a plurality a coordinated mirrors.

Referring to FIGS. 2 to 6, a lithography apparatus according to the invention will now be described. This lithography apparatus implement a process according to the invention and comprises:

a device 10 according to the invention for generating an output radiation through an output aperture 5,

an optical system 6, comprising at least one lens,

a planar mask 7,

a support 8 arranged to carry a wafer 9.

The device 10 for generating an output radiation comprises:

a plurality of radiation sources 11-14, each source generating a respective pulsed elementary radiation whose wavelengths include a respective desired range, each source being arranged for directing rays of its respective elementary radiation on said output aperture 5, each source comprising a respective plasma in which the respective elementary radiation is generated and deviation means 212, 2121, 2122 comprising means for setting up a controlled distribution of refractive indices of rays in a respective control region through which its respective elementary radiation passes and located in its respective plasma, so as to selectively deviate rays of its respective elementary radiation as a function of their wavelength, and

a temporal multiplexer 15 for temporally multiplexing the radiation sources in order to obtain at the output aperture 5 said output radiation.

The optical system 6 receives from the output aperture 5 rays of the elementary radiations emitted by the pulsed sources 11 to 14 and not stopped by the filtering windows 222, and process these rays by collimating them and/or making them converge in order to direct them onto the wafer 9. The mask 7 receives the rays from the optical system 6 and only lets pass to the wafer the rays that are in front of a transmission pattern, the rest of the rays being stopped by the mask. The plane of the mask 7 is optically conjugated with the plane of the wafer receiving the rays: typically, as illustrated in FIGS. 2 to 5, the rays of each elementary radiation are focused on the plane of the mask 7, and are also focused on the wafer. This can be done thanks to a lens assembly 16, comprising at least one lens, and disposed between the mask 7 and the support 8.

The temporal multiplexer 15 is arranged to send control signals to the sources 11 to 14. A control signal produce a generation of an elementary radiation by the radiation source receiving said control signal. The temporal multiplexer is arranged to control, to supervise and to coordinate in time the generations of elementary radiations by the radiations sources 11 to 14 one relative to the others. The temporal multiplexer typically comprises an analogical or digital circuit, a microprocessor or a computer. A user can select a desired coordination of the sources 11 to 14 thanks to capture means (typically a set of buttons and/or a keyboard) connected to the multiplexer.

All the sources 11 to 14 of the apparatus according to the invention illustrated in FIGS. 2 to 5 have common characteristics that will be described referring to FIG. 6, this figure illustrating one of the radiation sources 20 of the device according to the invention. This radiation source 20 is of the type disclosed in EP 1 673 785 B1.

This radiation source 20 comprises a chamber 21 which is generally closed but a side 210 of which is open to allow passage of rays from the chamber. The chamber 21 comprises a plasma 211 capable of producing an elementary radiation R0.

The elementary radiation comprises rays whose wavelengths correspond to a range of desired wavelengths. In a preferred but non-limiting application of the invention, the range of desired wavelengths is included in the interval [0-100 nm]. This range of desired wavelengths may therefore be included in the extreme ultra violet spectrum (EUV spectrum) or in the soft X-rays spectrum.

The chamber 21 is therefore capable of producing an elementary radiation, of which a significant quantity of the rays corresponds to the range of desired wavelengths. It is however possible that the elementary radiation contains rays whose wavelengths do not correspond exactly with the desired range, and/or that the source 20 emits certain debris with the elementary radiation. To prevent these undesirable effects, the source 20 comprises means for filtering the elementary radiation, these filtering means being capable of instituting a controlled distribution of refractive index of the rays in a control region 212 through which the elementary radiation passes, so as to selectively deviate the rays of the elementary radiation as a function of their wavelength. The control region is located within the chamber 21 itself. The control of the distribution of refractive index in the control region is obtained by controlling the distribution of electron density in the said control region, as disclosed in EP 1 673 785 B1.

The control region 212 is thus situated in the chamber 21, and so this control region is in the plasma 211 associated with the source 20. The control of the electron density distribution in the control region enables the trajectories of different rays of the elementary radiation to be influenced, as a function of the wavelength of these rays. This is illustrated in FIG. 6, which shows two general trajectories of two types of rays:

rays of a first wavelength λ1. These rays have a trajectory R1.

rays of a second wavelength λ2, which is less than the first wavelength λ1. These rays have a trajectory R2.

An electron density distribution is established in the control region such that the electron density is greater at a distance from a median line A of emission of elementary radiation than on the said median line of emission of the elementary radiation. It is mentioned that in the case illustrated here, the chamber typically has the shape of a round cylinder and the elementary radiation is emitted with a substantially axisymmetric distribution of rays, around the line A.

To create such an electron density distribution in the control region, energy is supplied to the plasma of the chamber 21 along the said line A. This energy supply may be effected, for example, by an electron beam or by laser radiation, directed into the control region along the axis defined by the line A. It enables the plasma to be ionised in the control region along the line A. Before this energy supply, a voltage has been established on terminals 2121, 2122 of the chamber containing the plasma, the said terminals being spaced in the direction generally defined by the median emission line of the elementary radiation.

A filtering window 222 is disposed at the focal point of the rays of the trajectory R2. This window corresponds to a means of collecting rays of the desired wavelengths, among the rays of the elementary radiation. It has been seen that the different rays coming from the elementary radiation RO were differently deviated by the electron density distribution existing in the control region, as a function of their wavelength. This selective deviation brings the rays associated with a given wavelength to converge towards a specific point of the line A—and this specific point will be termed the “focal point”. The position of the focal point on the line A (a position which may be defined by a curvilinear abscissa of a reference mark connected to the line A) therefore depends on the wavelength associated with this focal point. The focal points F1 and F2 respectively associated with the rays of trajectories R1 and R2 are shown in FIG. 6. The window 222 is therefore disposed at the focal point F2. This window has the function of allowing to pass only the rays arriving on the line A substantially at the level of the focal point F2 (that is, rays of wavelength λ2). For this purpose, the window 222 has an aperture 2220 which is preferably centred on the line A. In this way, windows may be disposed in any desired location of the line A, as a function of the wavelength which it is desired to isolate.

As mentioned before, a big and powerful source illustrated in FIG. 1 has a big etendue, usually greater than the 1-3 mm².sr requirement.

Each radiation source 20 of the lithography apparatus according to the invention combine in a same plasma means for generating an elementary radiation and a control region that plays the role of a lens. The source does not need any lens in front of his aperture 210 to focalize the elementary radiation. The radiation collection optical element of each source 20 is not a physical lens or a mirror distant from the plasma 211, but the plasma itself. This means that a plasma can collect the radiation produced by each radiation source 20 better, which leads to a small etendue of each radiation source 20, and a small etendue of the whole device 10. Each source 20 has a very small size and etendue compared to the source illustrated in FIG. 1. Thus, the etendue requirement is easily met by the device 10 according to the invention. Even if the etendue of the gathering of a plurality of sources is also proportional to the number of sources, the total etendue requirement of 1-3 mm².s is met in a device according to the invention because each radiation source 20 has an etendue between 0.001 and 0.1, typically of 0.01 mm².sr. For example, if the device 10 comprises one hundred sources 20, the device 10 would therefore have an etendue of 0.1 mm².sr, i.e. meeting the requirement. The device 10, having small and compact radiation sources 20, is compact.

All the sources of the devices 10 are arranged such that, if all these sources simultaneously generate a respective elementary radiation, then rays of these respective radiations simultaneously reach the output aperture 5, and they also simultaneously reach the wafer 9. That means that the apparatus according to the invention does not required the complicated mirror setup disclosed in U.S. Pat. No. 6,861,656.

Typically, the device 10 comprises around one hundred or more radiation sources 20. In the first realization mode of the lithography apparatus illustrated in FIGS. 2 and 3, the source apertures 210 of the radiation sources are grouped on a surface 16, this surface 16 being preferably a plane or a sphere portion, each aperture 210 being adjacent to at least one other aperture 210 along a first direction 17 and adjacent to at least one other aperture 210 along a second direction 18 different from the first direction 17. The first direction 17 is perpendicular to the second direction 18. In FIG. 7, each circle represents an aperture 210 of one of the sources 20. This way, the sum of all the radiation sources is very compact and the device 10 is small.

In the second realization mode of the lithography apparatus illustrated in FIGS. 4 and 5, the source apertures 210 of the radiation sources are also grouped on a surface, each aperture 210 being adjacent to at least one other aperture 210 along a first direction and adjacent to at least one other aperture 210 along a second direction different from the first direction 17. The sources 11, 13, 14 being oriented in the opposite direction from the output aperture 5, this surface comprise a middle part without aperture 210 in order to let the radiation pass from the radiation sources to the output window.

FIGS. 2 and 3 are respectively a first and second schematic view of the first realisation mode of a lithography apparatus according to the invention. In FIG. 2, only a part of the sources of this first realization mode is illustrated. The sources 11, 12, 13 illustrated in FIG. 2 generate one after the other elementary radiations, rays of which reach a same area of the mask 7. In FIG. 3, only an other part of the sources of this first realization mode is illustrated. The sources 14 illustrated in FIG. 3 simultaneously generate elementary radiations, rays of which reach different areas of the mask 7 in order to create a desired radiation pattern. In fact, the first realization mode comprises more than one hundred sources that can be coordinated like the illustrated sources 11, 12, 13 or like the illustrated sources 14. A given radiation source can even function like the sources 11 to 13, like the sources 14, like a reserve source or like a supportive source depending on how it is controlled by the multiplexer. In this first realization mode, for each radiation source, from said radiation source to the output aperture, the rays generated by said radiation source and reaching the output aperture are not subjected to any reflection. That means that the device 10 do not need mirrors between the radiation sources and the output aperture 5, the device 10 being thus small. Nevertheless, this first realization mode can comprise for at least one radiation source 20, between said at least radiation source and the output aperture, a mirror or a beam splitter that reflects rays generated by said at least radiation source, these reflected rays reaching not the output aperture 5. For example, these reflected rays can be used for power or wavelength measurements.

FIGS. 4 and 5 are respectively a first and second schematic view of the second realisation mode of a lithography apparatus according to the invention. In FIG. 4, only a part of the sources of this second realization mode is illustrated. The sources 11, 13 illustrated in FIG. 4 generate one after the other elementary radiations, rays of which reach a same area of the mask 7. In FIG. 5, only an other part of the sources of this second realization mode is illustrated. The sources 14 illustrated in FIG. 5 simultaneously generate elementary radiations, rays of which reach different areas of the mask 7 in order to create a desired radiation pattern. In fact, the second realization mode comprises more than one hundred sources that can be coordinated like the illustrated sources 11, 12, 13 or like the illustrated sources 14. A given radiation source 20 can function like the sources 11-13, like the sources 14, like a reserve source or like a supportive source depending on how it is controlled by the multiplexer.

Referring to FIGS. 2 to 5, the device 10 further comprises means 19 to measure a power of the output radiation, and a controller 22 arranged to control the temporal multiplexer according to a measurement of the power of the output radiation. The measured power of the output radiation is a time averaged power. The means to measure the power of the output radiation comprise, for each radiation source, a probe 19 disposed between the aperture 210 and the filtering window 222 of said source, this probe being arranged to measure a power of the pulsed radiation generated by said source, the power of the output radiation being equal to the average over time of the power of the pulsed radiations generated by the sources. Only one of the probes in showed in FIGS. 2 to 5. The controller 22 received the values of the measurement from the probes, and is connected to the multiplexer 15. The controller 22 typically comprises an analogical or digital circuit, a microprocessor or a computer.

In the process according to the invention implemented by the first or the second realization mode of lithography apparatus, the temporal multiplexer 15 can coordinate the radiation sources so that the radiation sources comprise:

an operation group comprising sources arranged to generate elementary radiations one after the other, these sources being preferably arranged to periodically generates elementary radiations, and

a supportive group comprising supportive sources arranged to generate elementary radiations only if the power of the output radiation generated by the operation group is lower than a minimum threshold value.

If the output radiation generated by the operation group is lower than the minimum threshold value, then the controller 22 send this information to the multiplexer 15, and the multiplexer activates one or more sources of the supportive group, in order to increase the power of the output radiation up to the minimum threshold value.

Likewise, if the output radiation generated by the operation group is greater than a maximum threshold value, then the controller 22 send this information to the multiplexer 15, and the multiplexer deactivates one or more sources of the operation group, the desactived sources generating no elementary radiation anymore, in order to decrease the power of the output radiation down to the maximum threshold value.

As shown in FIGS. 2 and 4, the sources 11 to 13 of the operation group and of the supportive group are preferably arranged to generate rays that reach a same area of the output aperture 5, a same area of the mask 7 and a same area of the wafer 9.

Thanks to the great number of radiation sources and to the multiplexer, the device 10 can reach a very large range of output power and output frequency of the output radiation. If each radiation source 20 has a respective maximum pulse generation frequency over which said source can not generate pulsed radiations, the temporal multiplexer can be arranged to coordinate the radiation sources in order to give to the output radiation an average frequency that is higher than the maximum frequencies of all the sources. As an example, if the lithography apparatus according the invention is gathering one hundred sources 20, each source having a power of 2 W and a maximum frequency of 2 kHz, the multiplexed sources would have a power of 200 W and a frequency of 200 kHz. In the prior art, it is hard to make a single source having a power of 200 W and a frequency of 200 kHz, whereas it is much simpler to make a source having a power of 2 W and a frequency of 2 kHz.

Furthermore, thanks to the controller 22, the output power is very stable.

In the process according to the invention, as shown in FIGS. 3 and 5, the temporal multiplexer 15 can coordinate the radiation sources in order to command simultaneous generations of elementary radiations by more than one source 14 in order to create a desired pattern of simultaneous radiations. A pattern of simultaneous radiations is a set of radiations drawing said pattern, and simultaneously reaching the output aperture, then simultaneously reaching the mask 7, then simultaneously reaching the wafer 9. The radiation pattern can be periodically generated.

FIGS. 8 to 11 illustrate examples of such radiation patterns, each circle illustrating in the plane of the mask 7 the radiation generated by one of the sources and reaching the mask 7. FIG. 8 illustrates a dot obtained by a plurality of superimposed radiations generated by a plurality of radiation sources. FIG. 9 illustrates a dipole pattern. FIG. 10 illustrates a vertical line pattern. FIG. 11 illustrates a pattern having a ring shape. The mask 7 can have various transmission patterns. The transmission pattern of the mask can diffract the radiations generated by the device 10. Advantageously, the radiation pattern can compensate the diffraction effects of the transmission pattern. For example, if the transmission pattern horizontally diffract radiations, the vertical line pattern of FIG. 10 compensates this diffraction.

In the process according to the invention implemented by the first or the second realization mode of lithography apparatus, the temporal multiplexer 15 can coordinate the radiation sources so that the radiation sources comprise a plurality of radiation groups:
each radiation group comprising a plurality of sources 20 simultaneously generating elementary radiations in order to create a respective radiation pattern,
the radiation groups generating their respective radiation patterns one after the other.

This allows combining the advantages previously disclosed:
compensating the diffraction of the mask 7, and
allowing a large range of the average frequency of the output radiation, and/or allowing a large range of the average power of the output radiation, and/or stabilizing the average frequency and/or power of the output radiation thanks to the controller 22.

In an embodiment of the process according to the invention, all the respective radiation patterns can be identical.

In an other embodiment, the respective radiation patterns can be different. The radiation patterns can gradually evolve from one shape to an other shape as they are successively generated. This way, the radiation pattern received by the mask is dynamically modified.

As illustrated in FIGS. 4 and 5, the second realization mode of the lithography apparatus comprises, for each radiation source, at least one mirror 23 reflecting to the output aperture rays generated by said source. This second realization mode further comprises means to modify the angular position of each mirror 23. The angular position of each mirror 23 can rotate according to two different angular degrees of freedom. Typically, the mirrors 23 are mounted on motors controlled by the multiplexer 15. These modification means can be used by a user, as illustrated in FIG. 5, to dynamically and continuously modify the respective area of the mask 7 and the respective area of the wafer 9 that are reached by each radiation source 14. This way, a radiation pattern received by the mask 7 can be dynamically and continuously modified. That means that the pupil fill factor of the mask 7 is dynamically variable during an exposure of the wafer 9. For the sake of clarity of FIGS. 4 and 5, only one mirror 23 is illustrated for each source 14. The best realization mode of the device 10 according to the invention comprises, for each radiation source 14, at least two mirrors 23 reflecting one after the others to the output aperture 5 rays generated by said source. This way, rays generated by a source 14 and reflected by the at least two mirrors 23 of this source 14 can reach any point or area of the mask 7 and of the wafer 9, by modifying the angular positions of these at least two mirrors 23. FIG. 12 illustrates three successive steps 24, 25, 26 of a radiation pattern dynamically modified from a vertical line shape 24 to a ring shape 26, each circle illustrating in the plane of the mask 7 the radiation generated by one of the sources and reaching the mask 7.

Finally, in the device 10, the measurement means 19 are arranged to detect a breakdown or a failure of at least one of the pulsed sources, the plurality of radiation sources comprising a reserve group comprising reserve sources arranged to generate radiations in place of each broken down or failing source. This way, if one radiation source has a problem, a technician can fix it or replace it while the lithography apparatus is still working, that is while the lithography apparatus is generating the output radiation having the desired power, the desired frequency and the desired pattern.

Of course, the invention is not limited to the examples which have just been described and numerous amendments can be made to these examples without exceeding the scope of the invention.

In particular, the filtering window 222 can be the same one for all the sources, and can preferably be the output aperture 5. In this variant, a part of each elementary radiation is focused on the output window.

Furthermore, the desired ranges can be different from one radiation source to an other one.

1. A process for generating an output radiation through an output aperture, said process comprising:
generating-pulsed radiations by a plurality of radiation sources each source being arranged for respectively
(i) generating within a respective plasma a respective pulsed elementary radiation whose wavelengths include a respective desired range,
(ii) directing rays of its respective elementary radiation on said output aperture,
for each source, distributing refractive indices of rays in a respective control region through which its respective elementary radiation passes and located in its respective plasma, so as to selectively deviate rays of its respective elementary radiation as a function of their wavelength,
and
temporally multiplexing said radiation sources so as to obtain at the output aperture said output radiation.

2. The process according to claim 2, characterized in that it further comprises detecting a breakdown of one of the radiation sources, and generating an elementary radiation by a reserve source that replaces said broken down source.

3. The process according to claim 1, characterized in that it further comprises a measurement of a power of the output radiation, and a control of the temporal multiplexing according to the measurement of the power of the output radiation.

4. The process according to claim 3, characterized in that the pulsed radiations generation comprises generating elementary radiations one after the other by operating sources, and generating at least one elementary radiation by at least one supportive source if the power of the output radiation generated by the operating sources is lower than a minimum threshold value.

5. The process according to claim 1, characterized in that a plurality of elementary radiations are simultaneously generated in order to create a desired radiation pattern.

6. The process according to claim 5, characterized in that it further comprises a dynamical modification of the desired pattern over the time.

7. The process according to claim 5, characterized in that the dynamical modification of the radiation pattern comprises, for at least one of the radiation sources, a modification of an angular position of at least one mirror reflecting to the output aperture rays generated by said radiation source.

8. The process according to claim 1, characterized in that an average frequency of the output radiation is higher than a maximum frequency of each radiation source.

9. A device for generating an output radiation through an output aperture, said device comprising:
a plurality of radiation sources, each source comprising means for generating a respective pulsed elementary radiation whose wavelengths include a respective desired range, each source being arranged for directing rays of its respective elementary radiation on said output aperture, each source comprising a respective plasma in which its respective elementary radiation is generated and deviation means comprising means for setting up a controlled distribution of refractive indices of rays in a respective control region through which its respective elementary radiation passes and located in its respective plasma, so as to selectively deviate rays of its respective elementary radiation as a function of their wavelength; and
a temporal multiplexer for temporally multiplexing the radiation sources in order to obtain at the output aperture said output radiation.

10. The device according to claim 9, characterized in that it further comprises means for detecting a breakdown of at least one of the pulsed sources, the plurality of radiation sources comprising a reserve group comprising at least one reserve source arranged to generate radiations in place of at least one broken down source.

11. The device according to claim 9, characterized in that it further comprises means for measuring a power of the output radiation, and means for controlling the temporal multiplexer according to a measurement of the power of the output radiation.

12. The device according to claim 11, characterized in that the plurality of radiation sources comprises:
an operation group comprising sources arranged for generating radiations one after the other; and
a supportive group comprising at least one supportive source arranged to generate radiations if the power of the output radiation generated by the operation group is lower than a minimum threshold value.

13. The device according to claim 9, characterized in that the temporal multiplexer is arranged to command simultaneous generations of radiations by more than one source in order to create a desired radiation pattern.

14. The device according to claim 13, characterized in that it further comprises means for dynamically modifying the radiation pattern.

15. The device according to claim 13, characterized in that it comprises, for at least one of the radiation sources, at least one respective mirror reflecting to the output aperture rays generated by said source.

16. The device according to claim 9, characterized in that at least one of the radiation sources is arranged to generate an elementary radiation, rays of which reach the output aperture and are not reflected from said radiation source to the output aperture.

17. The device according to claim 9, characterized in that each source generates its respective pulsed elementary radiation through a respective source aperture, a plurality of source apertures being grouped on a surface, the surface being preferably a plane or a sphere portion, each aperture grouped on the surface being adjacent to at least one other aperture grouped on the surface along a first direction and adjacent to at least one other aperture grouped on the surface along a second direction different from the first direction.

18. The device according to claim 9, characterized in that each radiation source has a respective maximum generation frequency of elementary radiations, the temporal multiplexer being arranged to give to the output radiation an average frequency that is higher than all the maximum frequencies of the sources.

19. The device according to claim 9, characterized in that it further comprises for at least one radiation source a respective filtering window on the downstream side of the control region of said source, said filtering window:
letting pass the rays generated by said source and inside of the desired wavelength range of said source; and
preventing the rays generated by said source and outside of the desired range of said source from reaching the output aperture.

20. The device according to claim 19, characterized in that the filtering window is substantially the same one for several of the sources, and is preferably the output aperture.

21. The device according to claim 9, characterized in that said means for setting up a controlled distribution of refractive indices comprise means for controlling the electron density distribution in said control region.

22. The device according to claim 9, characterized in that at least one desired range is located in the wavelength interval from 0 nanometre to 100 nanometres, preferably in the extreme UV spectrum or soft X-rays spectrum.

23. A lithography apparatus comprising a generating device according to claim 9.

24. A method of producing microelectronic components, particularly semiconductor components, using the lithography apparatus according to claim 23.
